(19) United States
(12) Patent Application Publication
(10) Pub. No.: US 2004/0068689 A1
(43) Pub. Date: Apr. 8, 2004

(54) Method and apparatus for CRC size reduction

(76) Inventor: Rahul Saxena, Sunnyvale, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/266,990

(22) Filed: Oct. 7, 2002

(51) Int. Cl. H03M 13/00

(52) U.S. Cl. 714/781

(57) ABSTRACT

A method and apparatus for replacing a CRC with a reduced size data integrity indication is disclosed. In one embodiment, a shared memory ethernet switch includes logic to replace a 4-byte CRC field of a frame with a 1 byte CRC prior to storing the frame in shared memory. Upon reading the frame from memory, the 1 byte CRC is used for error checking.

### BACKGROUND

1. Field

The invention relates to the field of data transmission, and in particular, to verifying the integrity of digital data transmissions using cyclic redundancy codes or other schemes.

2. Background Information

It is well known in the art to use error checking, in which an error calculated by a receiver of data, based on the content of a data transmission, is checked against a specified field of the received data. For example, Ethernet is a common networking protocol which uses CRCs (cyclic redundancy codes) to detect errors. As used herein, “Ethernet” refers to any and all of the current ethernet standards published by IEEE, including but not limited to the IEEE 802.3 standards committee, and any future ethernet standards, including ethernet, fast ethernet, gigabit ethernet, and others. For example, according to the IEEE Ethernet standard 802.3, a 4-byte CRC is calculated and appended to an Ethernet frame prior to transmission. Upon receipt, the receiver can recalculate the CRC and compare it to the CRC that was appended to the received frame. If the calculated CRC does not match the appended CRC, then there was a transmission error, and the frame is discarded. If there is a match, the frame is not discarded.

In a shared memory ethernet switch, there may be a second CRC check. After successful receipt of a frame from an input port, the frame will be sent to and stored in a shared memory. Because errors may be introduced when the frame is sent to, stored in, or read from, memory, a second CRC check is done. This second CRC check is done when the frame is read from memory, after determining the correct output port(s) for the frame. As in the case above, if the calculated CRC does not match the appended CRC, then there was an error, and the frame is discarded. If there is a match, the frame is not discarded.

This second CRC check uses valuable memory resources. During both the reading and the writing, 4 additional bytes are read to or written from the memory, thereby consuming memory bandwidth. In addition, storing the 4-byte CRC uses up memory space and may prevent the storage of other data. Due to the desire to increase network performance, it would be desirable to reduce this resource usage.

### BRIEF DESCRIPTION OF DRAWINGS

The subject matter regarded as the invention is particularly pointed out and distinctly claimed in the concluding portion of the specification. The invention, however, both as to organization and method or operation, together with objects, features, and advantages thereof, may best be understood by reference to the following detailed description, when read with the accompanying drawings in which:

FIG. 1 is a block diagram of portions of an embodiment of a shared memory ethernet switch;

FIG. 2 is a block diagram of portions of an embodiment a shared memory ethernet switch which includes logic for replacing a CRC with a reduced size CRC;

FIG. 3 is a flowchart of an embodiment of the process of replacing a CRC with a reduced size CRC.

### DETAILED DESCRIPTION

In the following detailed description, numerous specific details are set forth in order to provide a thorough understanding of the claimed subject matter. However, it will be understood by those skilled in the art that the claimed subject matter may be practiced without these specific details. In other instances, well-known methods, procedures, components, and circuits have not been described in detail so as not to obscure the claimed subject matter.

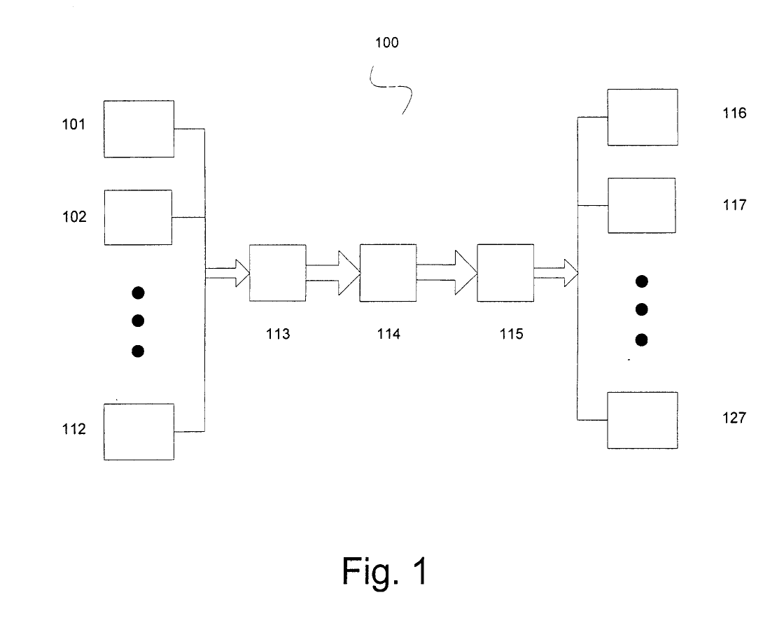

FIG. 1 is a block diagram of an embodiment of a portion of a shared memory ethernet switch 100. Data frames are received from the network by Ethernet receive (Rx) ports 101-112. After receipt, the frames are error-checked in CRC (cyclic redundancy code) 32 logic 113. The CRC 32 logic checks for errors as follows. When a frame is received, a 4 byte CRC may be computed. The computed value is checked against the 4-byte CRC field in the data frame. If the CRC comparison mismatches, it means that the frame was corrupted before being received by the receive port. In this case the frame is discarded and not further processed by the switch. If, however, the CRC values match, the frame is assumed to have been received error-free. In this case the frame is stored in frame memory 114. Switch 100 includes processing logic for determining the correct transmit port(s). Frames remain in frame memory while the switch determines the correct transmit port(s). Once switch 100 has determined to transmit a frame to a Tx port 116-127, the frame is read from frame memory 114. There is a chance that the frame was corrupted either when it was sent to memory 114, while it was in memory, or when it was read from memory. Thus, an additional CRC check is done. Here, a 4 byte CRC is checked in CRC-32 checker block 115. As with the case when the frame is received, if the CRCs match, the frame is forwarded to one or more of Tx ports 116-127, and if the CRCs do not match the frame is discarded. As can be seen, CRC checks are done twice, once when the frame is received by the switch 100, and then again after reading the frame from frame memory 114.

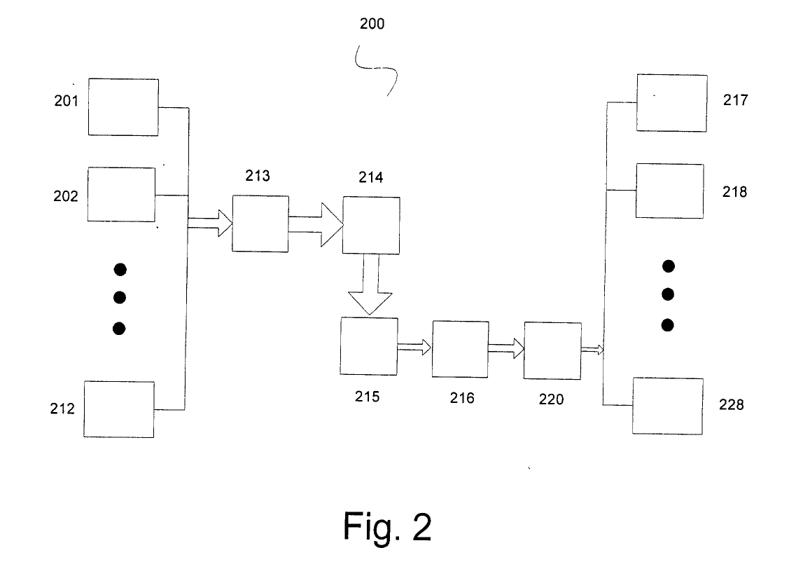

FIG. 2 is a block diagram of an embodiment of the claimed subject matter, a shared memory ethernet switch 200. Of course, the claimed subject matter is not limited to the details of this embodiment. For example, the claimed subject matter can be embodied in routers, firewalls, or any other network appliances and equipment. Similarly, the number of input and output ports is not limited. Ports 201-212 receive and transmit data over the network link. Data frames are received from the network by ethernet receive (Rx) ports 201-212. After receipt, the frames are error-checked in CRC (cyclic redundancy code) 32 logic 213. CRC 32 logic checks for errors as follows. When a frame received, a 4 byte CRC may be computed. The computed value is checked against the 4-byte CRC field in the data frame. If the CRC comparison mismatches, it means that the frame was corrupted before being received by the receive port. In this case the frame is discarded and not further processed by the switch. If, however, the CRC values match, the frame is assumed to have been received error-free. In this case the frame is stored in frame memory 215.

Improving now upon the prior art, in this embodiment, the frame passes through CRC replace logic 214 (CRL) prior to being stored in shared memory 215. The CRL logic calculates a 1-byte CRC for the frame, and then replaces the 4-byte CRC field with the newly calculated 1-byte CRC. There are many methods known to those of skill in the art to compute a 1-byte CRC, and the claimed subject matter is not limited in this respect. Neither is the claimed subject matter limited in respect of the actual size of the reduced size CRC. For example, the CRL logic may replace the existing CRC field with other reduced size CRCs, e.g. 3 bytes or 2 bytes, or any other size. In addition, the claimed subject matter is also not limited in respect of using a CRC for error correction in connection with storage of the frame in shared memory. For example, the 4-byte CRC field can be replaced with less bits from any other data integrity verification scheme, like parity bits.

Thus, for this particular embodiment, the frame that is stored in frame memory is smaller, resulting in using less memory space, and less memory bandwidth during the reading and writing of the frame to memory.

The switch 200 includes processing logic for determining the correct transmit port(s) and the correct transmit time(s). Frames remain in shared memory while the switch determines the correct transmit port(s) and the correct transmit time. Once the switch 200 has determined to transmit a frame to one or more Tx ports 217-228, the frame is read from the frame memory 215. There is a chance that the frame was corrupted either when it was sent to memory 215, while it was in memory, or when it was read from memory. Thus, an additional CRC check is done. According to this embodiment, a 1 byte CRC is checked in CRC-8 checker block 216. If the CRCs match, then the frame is prepared for transmission. This includes passing the frame through logic 220 for recalculating a 32-byte CRC and appending it to the frame according to the pertinent ethernet standard. Then the frame is forwarded to on or more of Tx ports 217-228. If the CRCs do not match the frame is discarded.

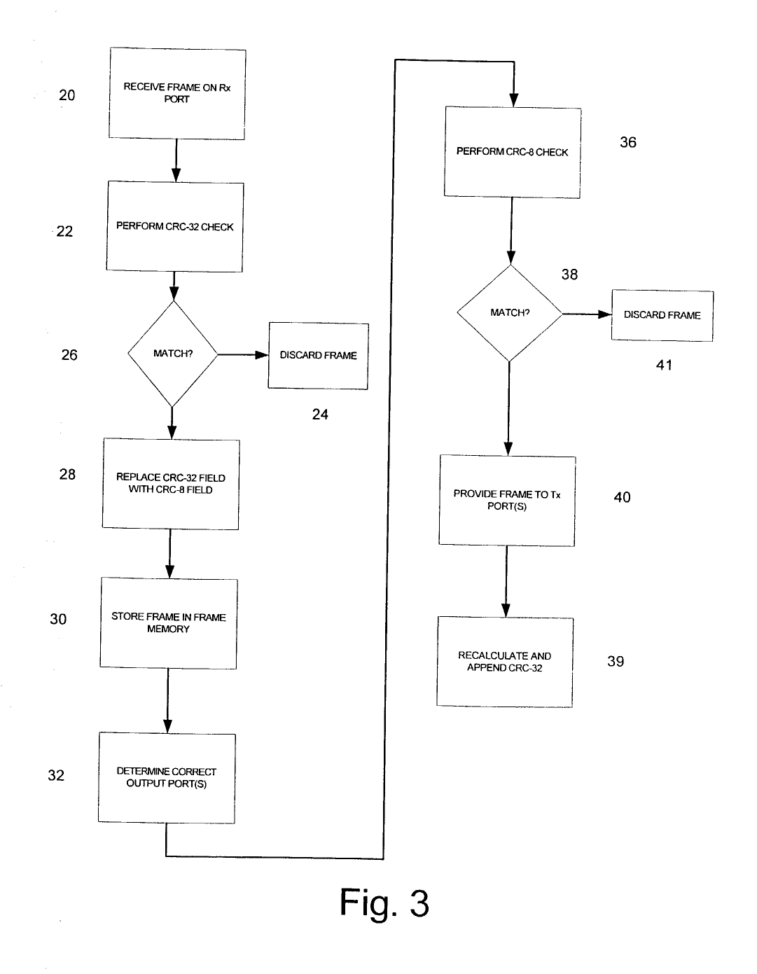

FIG. 3 is a flowchart of an embodiment of the claimed subject matter. Method 200 replaces the 4-byte CRC field of an ethernet frame with a 1-byte CRC field before the frame is stored in frame memory. When the frame is read from frame memory, error checking is performed by using the 1 byte CRC.

Method 200 includes receiving (20) an ethernet frame from a receive port; performing (22) a 4 byte CRC error check; discarding (24) the frame if the calculated CRC does not match the CRC field of the frame, and otherwise continuing (26) with processing; replacing (28) the 4 byte CRC field with a 1 byte CRC field; storing (30) the frame in frame memory; determining (32) the correct output port(s) and transmission times; reading (34) the frame from memory; performing (36) a 1 byte CRC error check; discarding (38) the frame if the calculated CRC does not match the CRC field of the frame; preparing the frame for transmission by recalculating and appending (39) to the frame a 4 byte CRC according to the pertinent ethernet standard; and providing (40) the frame to the transmit port.

Process 200 and the CRL logic described above may be implemented in programs executable by, for example, processors and/or controllers of various sorts known to those skilled in the art. Such programs may be implemented in a high level procedural or object-oriented programming language to communicate with a computer system. However, the programs may alternatively be implemented in assembly or machine language. The language may be a compiled or an interpreted language.

Such programs may be stored on an article of manufacture, such as a CD-ROM, hard disk, magnetic disk, non-volatile memory, or other forms of data and/or instruction storage known to those skilled in the art to be readable by a processor or controller, for example, which will be execute the instructions which make up the program.

While certain features of the claimed subject matter have been illustrated and described herein, many modifications, substitutions, changes and equivalents will now occur to those skilled in the art. For example, Asynchronous Transfer Mode (ATM) networking technology also uses CRC for error checking, and the claimed subject matter could be practiced in ATM. The claimed subject matter is not at all limited to any networking technology, so long as a CRC is used for error checking. It is, therefore, to be understood, that the appended claims are intended to cover all such modifications and changes.

What is claimed is:

1. A method comprising:
replacing the CRC, or any portion thereof, of a frame with a reduced-size data integrity indication.

2. The method of claim 1 further comprising:
storing the frame with the reduced-size data integrity indication in memory;
reading the frame with the reduced-size data integrity indication from memory.

3. The method of claim 1 wherein the reduced-size data integrity indication is a CRC, and further comprising:
calculating the reduced-size CRC;
comparing the calculated reduced-size CRC with the appended reduced-size CRC;
discarding the frame if the calculated reduced-size CRC is not equal to reduced-size CRC.

4. The method of claim 1 wherein the frame is an ethernet frame.

5. The method of claim 1 wherein the frame is an ATM frame.

6. The method of claim 1 wherein the reduced-size data integrity indication is a CRC and the frame is an ethernet frame and the CRC of the frame is 4-bytes and the reduced-size CRC is 1-byte.

7. The method of claim 1 wherein the reduced-size data integrity indication is a CRC and the CRC of the frame is 4-bytes and the reduced-size CRC is 1-byte.

8. An apparatus comprising:
CRC replacement logic, the CRC replacement logic to replace a CRC field, or any portion thereof, of the frame with a reduced-size CRC, or any portion thereof, prior to a frame being stored in memory.

9. The apparatus of claim 8 further comprising:
at least one input port;
at least one output port; and
memory, the input port to receive frames from a network, the output port to transmit frames to a network, and the memory to store the frames after receipt by the input port and prior to transmission by the output port.

10. The apparatus of claim 8 wherein the frames are ethernet frames.

11. The apparatus of claim 8 wherein the frames are ATM frames.

12. The apparatus of claim 8 wherein the CRC of the frame is 4-bytes and the reduced-size CRC is 1-bytes.

13. A shared-memory ethernet switch comprising:
at least one input port to receive frames from a network;
shared memory to store frames, the CRC replacement logic to replace a CRC field, or any portion thereof, of a frame with a reduced-size CRC, or any portion thereof, after a frame is received at an input port and before a frame is stored in memory.

14. The shared memory ethernet switch of claim 13 further comprising:
at least one output port for transmitting frames onto a network, the shared memory ethernet switch to recalculate the reduced-size CRC of a frame and compare it to the appended reduced-size CRC prior to the output port transmitting a frame onto the network.

15. An article comprising: a storage medium that stores instructions which when executed result in replacing the CRC, or any portion thereof, of a frame with a reduced-size data integrity indication prior to storing the frame in a memory.

16. The article of claim 15 wherein the frames are ethernet frames.

17. The article of claim 15 wherein the frames are ATM frames.

18. The article of claim 15 wherein the reduced-size data integrity indication is a CRC and the CRC of the frame is 4-bytes and the reduced-size CRC is 1-byte.

19. The article of claim 15 wherein the reduced-size data integrity indication is a CRC and further comprising instructions which when executed result in:
storing the frame with the reduced-size CRC in memory;
reading the frame with the reduced-size CRC from memory.

20. The article of claim 15 wherein the reduced-size data integrity indication is a CRC and further comprising instructions which when executed result in:
calculating the reduced-size CRC;
comparing the calculated reduced-size CRC with the appended reduced-size CRC;
discarding the frame if the calculated reduced-size CRC is not equal to reduced-size CRC.
